(19) United States
(12) Patent Application Publication
(10) Pub. No.: US 2008/0170360 A1
(43) Pub. Date: Jul. 17, 2008

(54) EXTENDABLE MOUSE WITH EXTENSION POLE

(76) Inventor: KUO-SHU CHENG, TAIPEI HSIEN (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/781,514

(22) Filed: Jul. 23, 2007

(30) Foreign Application Priority Data
Jan. 12, 2007 (CN) 200720117965.4

(51) Int. Cl. H05K 7/00

(52) U.S. Cl. 361/683

(57) ABSTRACT

An extendable mouse with an extension pole includes a bottom housing and a top housing. The top housing includes a forepart and a back part, the forepart covers the bottom housing, or, the forepart is in-molded with the bottom housing, a flexing sheath connects the forepart and the back part, and an extension pole is set inside the back part. The back part, the flexing sheath, and the extension pole joint extensionally with the forepart. The back part covers the bottom housing and can be pulled relative to the bottom housing. The shell of the extendable mouse of the present invention can be extended backwards more conveniently. The entire size of the mouse and the mini mouse especially when used for notebook computers is increased. Hence, integrality and the sense of looks are improved.

### BACKGROUND OF THE INVENTION

1. Field of the Invention

The present invention relates to a computer mouse, and more specifically to an extendable mouse, the shell of which can be extended.

2. Description of the Prior Art

A computer mouse is an accessory of a computer. Except for some main technical parameters, there are three basic requirements for the shape of a computer mouse: that they are easily and comfortable held in the user's hand to operate; they have an attractive exteriority. Furthermore, it is necessary for a user to store up the mouse conveniently. Some novel designs have been provided, such as designs for a user to adjust the size of a mouse. According to a shape of user's hand, the computer mouse can be extended when they are being used. After use, the computer mouse can be drawn close for storage. This type of computer mouse is especially common used for notebook computers. In fact, an extendable mouse isn't widely used. Three main reasons for their lack of popularity are that the designs are somewhat complicated and difficult to implement, the appearance of an extendable mouse usually lacks integrality, and when extending the mouse some components, such as the circuit boards set on the bottom housing, will be exposed. Hence, the structure of the mouse is short of integrality of the looks. Furthermore, some designs are inconvenient to operate and easily function improperly. Moreover, a large mouse is usually sold for desktop computers, and a mini mouse for notebook computers, the sizes of which cannot be increased or be reduced.

Hence, the inventors of the present invention believe that these shortcomings above are able to be improved upon and suggest the present invention which is of a reasonable design and is an effective improvement bottom housing on deep research and thought.

### SUMMARY OF THE INVENTION

The present invention aims to solve the disadvantages of the prior arts. Applicant improved the structure of a mouse and designed an extendable mouse. The extendable mouse is provided for an object that when using the extendable mouse, it can be extended to increase the size somewhat. After use, it can be drawn close to recover to its initial size. Its size is convenient for carrying around and storing.

To achieve the above-mentioned object, an extendable mouse having an extension pole is disclosed, and which mechanical structure is simple. The extendable mouse with an extension pole comprises a bottom housing and a top housing. The top housing comprises a forepart and a back part. The forepart covers the bottom housing, or, can be in-molded with the bottom housing. An extension pole is set inside the back part. The back part and the extension pole extensionally joint with the forepart. The back part covers the bottom housing and can be pulled relative to the bottom housing.

The back part with the extension pole can be extended backwards or contract forwards corresponding to the forepart synchronously. When extending them backwards synchronously, the shell of the extendable mouse is extended to make the entire size of the extendable mouse increased, thereby making the operation of the extendable mouse more comfortable for the user. When contracting forwards, the extendable mouse recovers to its initial size, which is convenient for storing.

The extending and the constricting of the back part, and the extension pole, corresponding to the forepart are adjustable and selectable. According to the needs of users, the back part is adjusted and selected to extend or contract relative to the forepart.

The extension pole is horizontally set inside the back part and is disposed parallel in shaft length axis direction of the extendable mouse. The front end and the back end of the extension pole are respectively fixed onto the bottom housing and the back part.

The structure of the extension pole is unlimited. The following embodiment shows the extension pole sliding into a sheath tube joint, which is similar to an extension pole of antenna. Moreover, the extension pole can be a sliding mortise and tenon joint.

The bottom housing, the forepart and the back part comprise a guiding structure correspondingly. A tenon joint element is disposed on the external surface of the bottom housing or on the external surface of the forepart and another tenon joint element is disposed on the internal surface of the back part. The both tenon joint elements are corresponding to each other. The guiding structure is not limited as above-mentioned.

Furthermore, a positioning device for the back part is disposed on the bottom housing so as to locate the back part 3 on a predetermined position.

The size and the shape of the contacting portion between the forepart and the back part are corresponding to the internal surface of the bottom housing so that the device inside the mouse is covered even when the mouse is extended for using. Accordingly, the mouse in the extended state is still has good looking and the designed product is improved.

Compared to the prior art, the extendable mouse of the present invention has the following advantages:
1. The shell of the extendable mouse can be conveniently extended backwards with adjustable and selectable. Hence, the entire size of the mouse is increased, especially for that of a mini mouse used for notebook computers. The operation of the mouse is more useful, more comfortable, more flexible, and more universal. Users can extend the shell when using the mouse, and contract it after use for easier storage.
2. The exposed part of the components are concealed and set on the bottom housing. Hence, integrality and sense of beauty are enhanced.
3. The inside structure and the keystroke of the extendable mouse are unchanged. Hence, manufacturing the device is convenient.
4. Manufacturing costs are little changed, however applicability is enhanced, and the visual effect is faultless. Hence, the market competitive is enhanced.

To further understand the features and technical contents of the present invention, please refer to the following detailed description and drawings related to the present invention. However, the drawings are only to be used as references and explanations, and not to limit the present invention.

### BRIEF DESCRIPTION OF THE DRAWINGS

FIG. 1 is a side view of an extendable mouse before extension of the present invention;

FIG. 2 is a side view of the extendable mouse after extension of the present invention.

FIG. 3 is a top view of the extendable mouse after extension of the present invention.

### DETAILED DESCRIPTION OF THE INVENTION

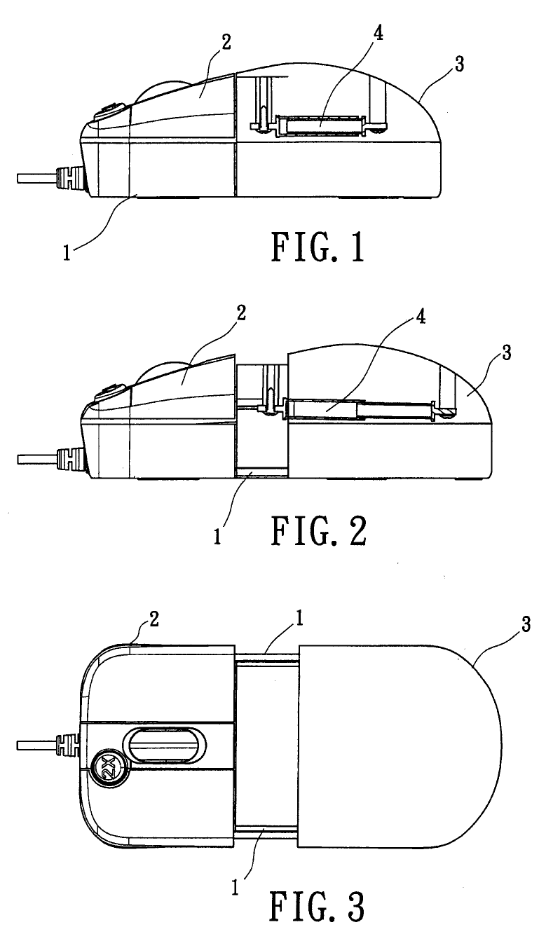

The embodiments of the present invention are described referring to FIGS. 1-3.

The extendable mouse of the present invention includes a bottom housing 1 and a top housing. The top housing includes a forepart 2 and a back part 3. The forepart 2 covers the bottom housing 1 and they are connected and jointed to each other. Alternatively, the forepart 2 is in-molded with the bottom housing 1. An extension pole 4 is set inside between the forepart 2 and the back part 3. The back part 3 and the extension pole 4 extensionally joint with the forepart 2. The back part 3 covers the bottom housing 1 and can be pulled relative to the bottom housing 1.

The back part 3 connected with the extension pole 4 can extend backwardly or contract forwardly relative to the forepart 2 synchronously.

The back part 3, and the extension pole 4 can be adjusted and selected to be extended or contracted relative to the forepart 2. The adjustment is controlled by the extension pole 4. When the back part 3 is lightly pulled or pushed by the hand of a user, the extension pole 4 synchronously make the extendable mouse agilely extend backwards or contract forwards. The final size can be selected according to the needs of the user, if the user desires a larger size, he or she pulls the extendable mouse a little. In other words, the size of the extendable mouse is adjustable depending on the user's demand in a predetermined range of the length of the extension pole 4.

The extension pole 4 is horizontally set inside the back part 3 and is disposed parallel in shaft length axis direction of the extendable mouse. The front end and the back end of the extension pole 4 are respectively fixed onto the bottom housing 1 (or the forepart 2) and the back part 3.

The structure of the extension pole 4 is unlimited. The following embodiment shows that the structure is a sliding sheath tube joint, which is similar to the structure of an extension pole of antenna. Alternatively, the structure is a sliding mortise and tenon joint.

The bottom housing 1, the forepart 2 and the back part 3 comprise a guiding structure correspondingly, such as corresponding tenon joint elements. In detail, a tenon joint element is disposed on the external surface of the bottom housing 1 or on the external surface of the forepart 2 and another tenon joint element is disposed on the internal surface of the back part 3. The both tenon joint elements are corresponding to each other. The guiding structure is not limited as above-mentioned.

Furthermore, a positioning device for the back part is disposed on the bottom housing 1 so as to locate the back part 3 on a predetermined position.

The size and the shape of the contacting portion between the forepart 2 and the back part 3 is corresponding to the internal surface of the bottom housing 1 so that the device inside the mouse is covered even when the mouse is extended for using. Accordingly, the mouse in the extended state is still has good looking and the entirety of the mouse is improved.

What is disclosed above are only the preferred embodiments of the present invention, and therefore it is intended that the present invention not be limited to the particular embodiment disclosed. It should be understood by those skilled in the art that various equivalent changes may be made depending on the specification and the drawings of present invention without departing from the scope of the present invention.

What is claimed is:

1. An extendable mouse with an extension pole, comprising:
a bottom housing;
a top housing comprising a forepart and a back part, wherein the forepart is in-molded with the bottom housing or connected to the bottom housing; and
an extension pole set inside the back part, wherein the extension pole joint extensionally with the forepart and is pulled relatively to the forepart

2. The extendable mouse as claimed in claim 1, wherein the back part and the extension pole extend backwardly or contract forwardly relatively to the forepart synchronously.

3. The extendable mouse as claimed in claim 1, wherein the extension pole is horizontally set inside the back part and is disposed parallel in shaft length axis direction of the mouse, a front end and a back end of the extension pole are respectively fixed onto the forepart and the back part.

4. The extendable mouse as claimed in claim 1, wherein the extension pole is a sliding sheath tube joint, or, is a sliding mortise and tenon joint.

5. The extendable mouse as claimed in claim 1, wherein the bottom housing, the forepart and the back part comprise a guiding structure correspondingly.

6. The extendable mouse as claimed in claim 5, wherein the guiding structure is a tenon joint element disposed on the external surface of the bottom housing or on the external surface of the forepart corresponding to a tenon joint element disposed on the internal surface of the back part.

7. The extendable mouse as claimed in claim 1, wherein a positioning device for the back part is disposed on the bottom housing.
